(19) United States
(12) Patent Application Publication
(10) Pub. No.: US 2010/0079863 A1
(43) Pub. Date: Apr. 1, 2010

(54) OPTICAL ELEMENT, METHOD FOR PRODUCTION THEREOF, AND USAGE THEREOF

(75) Inventors: Michael Thiel, Karlsruhe (DE); Goerg Von Freymann, Karlsruhe (DE); Martin Wegener, Karlsruhe (DE)

Correspondence Address: VENABLE LLP, P.O. BOX 34385, WASHINGTON, DC, 20043-9998, US

(73) Assignee: Forschungszentrum Kartsruhe Gmbh, Karlsruhe (DE)

(21) Appl. No.: 12/312,046

(22) PCT Filed: Aug. 4, 2007
(86) PCT No.: PCT/EP2007/006912

§ 371 Date: Apr. 23, 2009

(30) Foreign Application Priority Data
Oct. 26, 2006 (DE) 10-2006-050.580.8

(51) Int. Cl. G02B 27/28; G02F 1/13; B29D 11/00; G03F 7/00

(52) U.S. Cl. 359/492; 359/490; 349/194; 349/187; 264/1.37; 430/2

(57) ABSTRACT

The invention relates to an optical element, a method for the production thereof, and the usage thereof as an isolator or polarizer. An inventive optical element for a frequency window of the electromagnetic spectrum comprises a first component which has the function of a quarter wavelength plate, and a second component joined thereto which has a circular dichroism. When the first component is exposed to a linearly polarized wave, the optical element can be used as an optical isolator. When, however, the second component is exposed to the linearly polarized wave, the optical element can be used as an optical polarizer. An inventive optical element which is used as an optical isolator can be deployed in laser systems to reduce or suppress the feedback of the laser. In addition, windows can be thus produced which in a specific frequency window are transparent in only one direction. Unidirectional thermal insulation is thereby produced for the infared wavelength region.

The invention relates to an optical element, a method for producing said element and its use as optical isolator or polarizer.

On optical element has the characteristic of allowing electromagnetic radiation, in particular from the ultraviolet, visible and infrared frequency range, to travel (propagate) essentially only in one direction within a specific frequency window and to weaken or completely suppress the transmission of a returning light wave. As a result, optical isolators reduce and/or prevent in particular the problem of feedback in lasers, which considerably interferes with the laser operation, especially the operation of semiconductor lasers.

Known from the prior art are optical isolators that operate based on the Faraday Effect, for which a static magnetic field rotates the polarization of the light. If a Faraday element of this type is placed between two polarizers, positioned so as to be rotated by an angle of 45° relative to each other, then an optical isolator is formed if the polarization is rotated by an angle of precisely 45° with the aid of the Faraday element, wherein this adds up to an angle of 90° on the return path. However, when configuring an optical isolator of this type using the Faraday Effect, a static magnetic field is required.

An optical polarizer has the characteristic that it provides within a specific frequency window a fixed polarization state for the electromagnetic radiation, especially in the ultraviolet, visible and infrared frequency range. Optical polarizers are therefore used in nearly all optical configurations.

Optical polarizers are known from the prior art, which function based on the Brewster angle. Polarizers of this type must therefore be operated with an angle of incidence that clearly deviates from a perpendicular angle of incidence. In addition, the polarization function strongly depends on the angle of incidence.

An optical diode for circular polarized light is known from the document by J. Hwang, M. H. Song, B. Park, S. Nishimura, T. Toyooka, J. W. Wu, Y. Takanishi, K. Ishikawa and H. Takezoe, Electro-tunable optical diode based on photonic bandgap liquid-crystal heterojunctions, Nature Mater. 4, page 383, 2005. However, this optical diode is not suitable for the isolating of light. For example, if right-handed circular polarized light impinges on the optical diode, it is transmitted. By placing a mirror behind the optical diode, the right-handed circular polarized light is converted to left-handed circular polarized light, which can propagate unhindered through the optical diode whereas the light propagation in an optical isolator should be weakened or suppressed completely in return direction.

Starting with this premise, it is the object of the present invention to propose an optical element, a method for producing said element and the use of this element as optical isolator and/or polarizer, which does not have the aforementioned disadvantages and restrictions.

The optical element in particular should not require a static magnetic field when it is used as optical isolator, so that a more compact design is possible and it can also be used in magnetic-field sensitive applications.

In particular when used as optical polarizer, the optical element should not function based on the Brewster angle.

This object is solved with respect to the optical element by the features disclosed in claim 1, with respect to the production method by the steps disclosed in claim 10 or 11, and with respect to the use by the content disclosed in claims 12 and 15. The dependent claims respectively describe advantageous embodiments of the invention.

An optical element according to the invention comprises a compact photonic heterostructure, which has an isolating effect for a specific, scalable frequency window. The heterostructure comprises at least two components, wherein the first component takes on the function of a quarter-wavelength plate and the second component has a circular dichroism.

The function of the first component as quarter-wavelength plate (λ/4 plate) is preferably made available in the form of an achromatic or a super-achromatic delay plate, in particular one made of quartz and MgF₂. With this, the optical element can be used for a particularly broad frequency window from the electro-magnetic spectrum.

According to one alternative embodiment, the quarter-wavelength plate is a structure composed of parallel-arranged lamellas. The height of the lamellas in that case is selected such that the one component of the electrical field is phase-displaced by precisely one quarter wavelength, relative to the other component that is positioned perpendicular thereto. To achieve the best possible effect for the wavelength range around 1500 nm, a lamella height of 4 μm is required for a lamella spacing of 1 μm and a refractory index of n=1.57.

The second component is composed of a material with a circular dichroism, meaning a material through which right-handed circular and left-handed circular polarized light passes (is transmitted) differently. A material of this type is characterized in that it cannot be brought into coincidence with its mirror image.

According to one preferred embodiment, a chiral, photonic crystal is used for this. Particularly preferred is a photonic crystal provided with a plurality of parallel arranged spirals, for which the longitudinal axes are arranged perpendicular to the optical axis for the first component.

Furthermore preferred is the use of a chiral, photonic crystal, which is composed of double-refracting anisotropic layers that are turned relative to each other by an angle unequal to 90°.

According to an alternative embodiment, the second component can suitable consist of tourmaline and specific liquid crystals, especially cholesteric liquid crystals, wherein the latter in particular can be produced through self-assembly.

An optical element according to the invention can be used either as optical isolator or as optical polarizer, depending on whether the first or the second component is admitted with a linear polarized wave.

If the first component is admitted with a linear polarized wave, then the optical element is used as an optical isolator. An optical isolator of this type can be used in principle for any laser system to reduce or suppress the laser feedback, wherein the optical isolator is preferably used in semiconductor lasers for the telecommunications field, in the near infrared range.

The mode of operation of the optical isolators according to the present invention can be explained as follows. If the optical axis for the quarter-wavelength plate is aligned at an angle of 45°, relative to the plane of incidence for the light, then the quarter-wavelength plate generates circular polarized light from the incident linear polarized light, which may come from a laser. This circular polarized light subsequently enters the chiral component and is either transmitted or reflected, depending on whether it is left-handed or right-handed. If the chiral component is right-handed, then the propagation of right-handed circular polarized light is suppressed. If the chiral component is left-handed, then the propagation of left-handed circular polarized light is suppressed. Thus, if the light returning to the optical isolator has precisely the opposite handedness, the arrangement has a non-reciprocal character, meaning the light cannot propagate through the isolator in the return direction.

With an optical isolator, to the invention, which is provided with an additional polarizer as fourth component, the reverse propagation of light through the isolator within a specific frequency window is reduced considerably or is prevented completely, thus making it possible to have specific frequency windows through which ultraviolet light or visible light can pass through in one direction only. Scaled down to the infrared wavelength range, it results in unidirectional heat isolation: that is to say, heat radiation can enter a passive or energy-efficient house from the outside, but the heat radiation cannot leave the house.

The optical element is used as optical polarizer for generating polarized ultraviolet, visible, or infrared light if the second component is admitted with a linear polarized wave.

The mode of operation for the optical polarizer according to the present invention can be explained as follows. If non-polarized light falls upon a component having a circular dichroism, this component generates a reflected share and a transmitted share of the light, wherein both shares are circular polarized. If the optical axis of the quarter-wavelength plate is oriented at an angle of 45° relative to the plane of incidence for the light, then the quarter-wavelength plate generates linear polarized light from the circular polarized light.

A circular polarized reflected share and a linear polarized transmitted share are thus generated with the embodiment according to the invention, using a first and a second component, wherein the first component has a circular dichroism and the second component is a quarter-wavelength plate.

For the special embodiment having three components, a third component is provided that follows the second component, wherein the optical axis of the third component that is again a quarter-wavelength plate is arranged perpendicular to the optical axis of the first component. In that case, the reflection is also linear polarized, but rotated by 90° relative to the transmitted polarization.

An optical element according to the invention can be produced with the aid of direct laser writing. Larger surfaces can be produced with the aid of so-called microlens-arrays using direct laser writing or holographic methods. A further method that can be used is the deposition under a glancing angle, also referred to as glancing angle deposition (GLAD).

The invention has the advantages mentioned in the following.

In contrast to the Faraday isolators, the optical elements according to the invention which are used as optical isolators do not require a static magnetic field. By omitting the requirement for a static magnetic field, it is possible to use these isolators for magnetic-field sensitive applications and to produce optical isolators that are thinner and have larger surfaces. The optical isolator according to the invention can have an extremely compact design, thus making possible the easy integration into optical systems, e.g. behind the output mirror of a laser.

Optical elements according to the invention that are used as optical polarizers do not have to be operated under a specific angle of incidence, the Brewster angle, which noticeably deviates from the perpendicular angle of incidence. For small angles, the dependence of the polarization on the angle of incidence is low.

In the following, the invention is explained in further detail with the aid of exemplary embodiments and the Figures, wherein these show in:

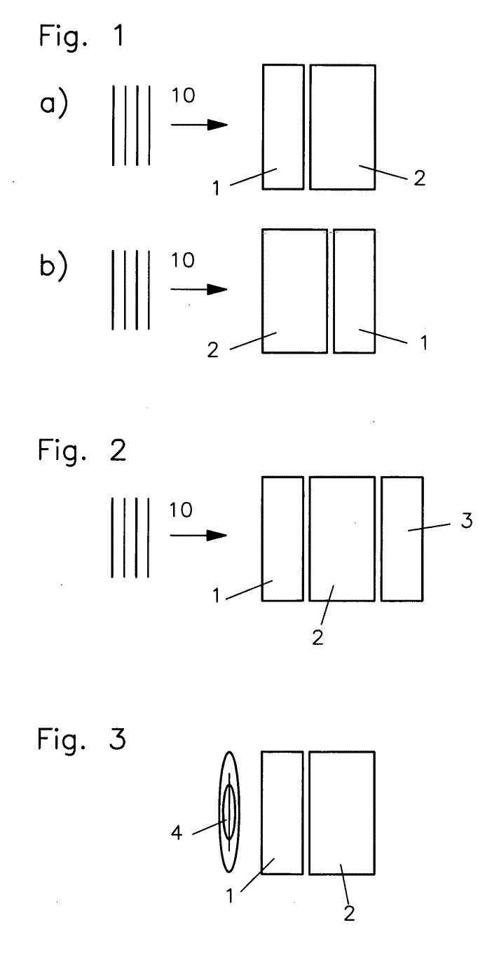

FIG. 1 A schematic representation of an optical element consisting of two components to be used either as optical isolator (a) or as optical polarizer (b);

FIG. 2 A schematic representation of an optical element consisting of three components;

FIG. 3 A schematic representation of an arrangement consisting of an optical isolator with two components, with a polarizer as fourth component;

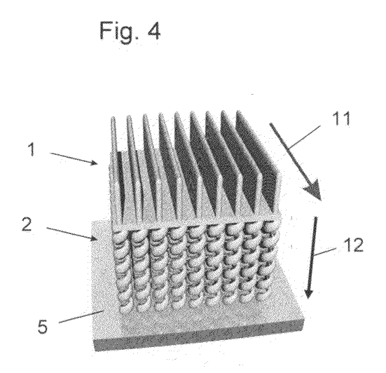

FIG. 4 An example of an optical element consisting of two components, having a lamella structure and a spiral structure;

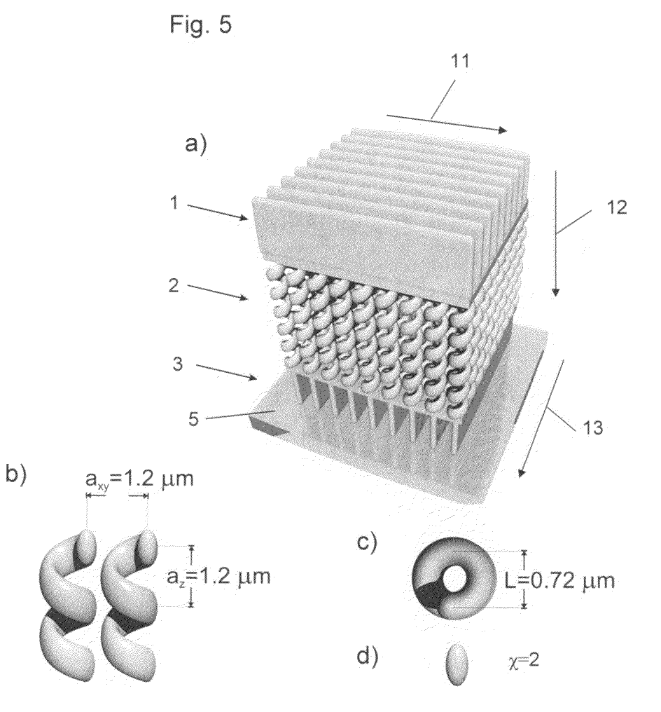

FIG. 5 An example of an optical element consisting of three components having lamella structures and a spiral structure;

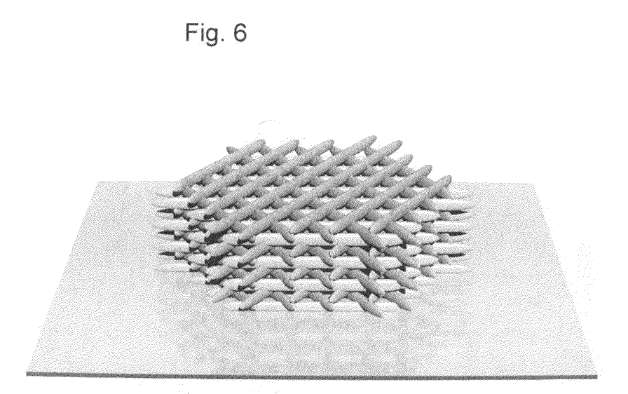

FIG. 6 A further example for the second component of an optical element;

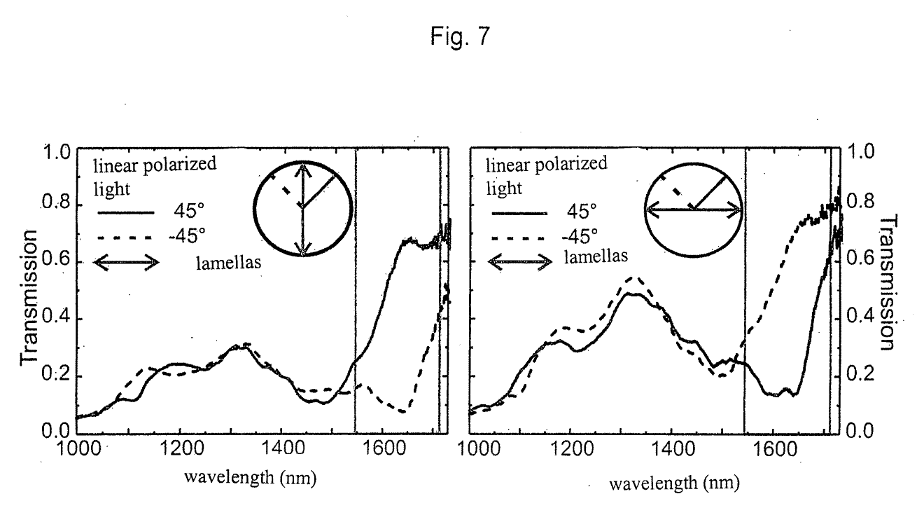

FIG. 7 Transmission spectra covering the wavelength of an optical element consisting of two components.

FIG. 1a) schematically illustrates an optical element according to the invention that is used as optical isolator, wherein this optical element comprises a first component 1 in the form of a quarter-wavelength plate that is admitted with a linear polarized wave 10 and furthermore comprises a second component 2, which has a circular dichroism.

FIG. 1b) schematically shows an optical element according to the invention that is used as optical polarizer, wherein the second component 2 with a circular dichroism is admitted with a linear polarized wave 10, and wherein the first component 1 is again a quarter-wavelength plate.

FIG. 2 schematically shows an optical element according to the invention, which is admitted with a linear polarized wave 10 and comprises a first component 1 in the form of a quarter-wavelength plate, a second component 2 with a circular dichroism, and a third component 3 in the form of an additional quarter-wavelength plate.

FIG. 3 schematically shows an arrangement according to the invention, comprising an optical element that is composed of a first component 1 in the form of a quarter-wavelength plate, a second component 2 with a circular dichroism, and an additional fourth component in the form of a polarizer 4.

FIG. 4 shows an example of an optical element positioned on a substrate 5, for which the first component 1 takes the form of a lamella structure and the second component 2 is embodied as a spiral structure, wherein the optical axis 11 for the first component 1 is positioned perpendicular to the optical axis 12 for the second component 2. An optical element of this type was produced in the laboratory with the aid of the direct laser writing technique.

FIG. 5a) illustrates an example of an optical element that is positioned on a substrate 5, for which the first component 1 takes the form of a lamella structure, the second component 2 is embodied as a spiral structure, and the third component 3 is again embodied as a lamella structure, wherein the optical axis 11 of the first component 1 is positioned perpendicular to the optical axis 12 of the second component 2 as well as to the same optical axis 13 of the third component 3. An optical element of this type was also produced in the laboratory with the aid of the direct laser writing technique.

FIGS. 5b), c) and d) show preferred dimensions for the spiral structure of the chiral photonic crystal, used as optical element in the telecommunications field, meaning for wavelengths ranging from 1000 nm to 1600 nm. The spacing and the period for the spirals should be 1 μm to 1.5 μm in this case, preferably approximately 1.2 μm while the diameter for spirals should be in the range of 0.5 μm to 1 μm, preferably approximately 0.72 μm. For the voxel form in the direct laser writing, a ratio of x=2 was selected, wherein a ratio of x=1 to x=5 is generally also suitable. Suitable materials for use are polymer photo resists, for example SU-8, chalcogenide glass materials such as As₂S₃, or silicone.

FIG. 6 shows a different example for the second component of an optical element, which consists of a photonic crystal located on a substrate, wherein this crystal is composed of double-refracting anisotropic layers, which are rotated relative to each other by an angle unequal to 90°. Photonic crystals of this type, in most cases with an angle of 90°, are referred to as having a wood-pile structure.

FIG. 7 shows experimentally recorded transmission spectra for an optical element according to the invention, extending over a wavelength range of 1000 to approximately 1750 nm, wherein the optical element consists of two components of the negative polymer lacquer SU-8 (refractory index n=1.57). According to FIG. 4, a lamella structure with a lattice constant of 1 μm and a height of 4 μm functions as quarter-wavelength plate. A spiral structure with a lattice constant of 1.2 μm is used for the chiral element.

The transmission spectra clearly show noticeable transmission changes in the transmission range of 1500 nm to approximately 1800 nm if the irradiated light hits the vibration plane at an angle of 45° or −45°. In addition, the main axis is rotated by 90°. As expected, complementary results are achieved. As a result, it has been proven that this optical element is suitable for use in a frequency window ranging from 170 to 200 THz.

1. An optical element for receiving radiation having a frequency range in the electro-magnetic spectrum, the optical element comprising:
a first component comprising a first quarter-wavelength plate; and
a second component comprising a circular dichroism located downstream from the first component with respect to the radiation.

2. The optical element according to claim 1, further comprising a third component located downstream from the second component with respect to the radiation, wherein the third component comprises a second quarter-wavelength plate having an optical axis extending perpendicular to an optical axis of the first component.

3. The optical element according to claim 1, further comprising a third component connected to the first component, wherein the third component comprises a polarizer arranged parallel to the first component.

4. The optical element according claim 1, wherein the first quarter-wavelength plate comprises an achromatic plate or a super-achromatic delay plate.

5. The optical element according to claim 1, wherein the first quarter-wavelength plate comprises parallel-arranged lamellas.

6. The optical element according claim 1, wherein the second component comprises a chiral photonic crystal.

7. The optical element according to claim 6, wherein the chiral photonic crystal includes a plurality of parallel arranged spirals each having a longitudinal axis, wherein longitudinal axes of the plurality of parallel arranged spirals are arranged perpendicular to an optical axis of the first component.

8. The optical element according to claim 6, wherein the chiral photonic crystal comprises double-refracting anisotropic layers, wherein the double-refracting anisotropic layers are angled relative to each other by an angle unequal to 90°.

9. The optical element according to claim 1, wherein the second component comprises cholesteric liquid crystals.

10. A method for producing the optical element of claim 1, comprising using a direct laser writing technique or a holographic method.

11. A method for producing the optical element of claim 9, comprising producing the second component through self-assembly of the cholesteric liquid crystals.

12. A method of using the optical element according to claim 1 as an optical isolator, comprising admitting the first component with a linear polarized wave.

13. The method of claim 12, further comprising using the optical element to reduce feedback in a laser.

14. The method of claim 12, further comprising reducing the propagation of ultraviolet, visible or infrared light in one direction.

15. A method of using the optical element according to claim 1 as an optical polarizer, comprising admitting the second component by a linear polarized wave.
